(19) United States
(12) Patent Application Publication
(10) Pub. No.: US 2024/0210476 A1
(43) Pub. Date: Jun. 27, 2024

(54) APPARATUS AND METHOD FOR RECOMMENDING CHARGING OF BATTERY IN ELECTRIC VEHICLE

(71) Applicant: Hyundai Kefico Corporation, Gunpo (KR)

(72) Inventors: Hyun Ki Shin, Seongnam (KR); Hyung Jin Shin, Seoul (KR)

(21) Appl. No.: 18/514,190

(22) Filed: Nov. 20, 2023

(30) Foreign Application Priority Data
Dec. 22, 2022 (KR) 10-2022-0181732

(51) Int. Cl. G01R 31/36; B60L 58/12; G01R 31/367; G01R 31/3828

(52) U.S. Cl. CPC G01R 31/3648; B60L 58/12; G01R 31/367; G01R 31/3828

(57) ABSTRACT

An apparatus for recommending charging of a battery in an electric vehicle includes: a battery consumption measurement module for measuring a daily battery consumption of the battery; a distribution model generation module for generating a distribution model for the daily battery consumption by using the measured daily battery consumption; and a recommendation module for providing a recommendation for charging of the battery based on the distribution model and a current state of charge of the battery.

### CROSS-REFERENCE TO RELATED APPLICATION(S)

This application claims under 35 U.S.C. § 119(a) the benefit of Korean Patent Application No. 10-2022-0181732 filed in the Korean Intellectual Property Office on Dec. 22, 2022, the entire contents of which are incorporated herein by reference.

### BACKGROUND

### (a) Technical Field

The present disclosure relates to an apparatus and a method for recommending charging of a battery in an electric vehicle.

### (b) Description of the Related Art

A battery life or range that an electric vehicle can be driven at the time of charging the electric vehicle is an important indicator that may affect a user's comfort level with the electric vehicle, and which may impact desirability and competitiveness of the electric vehicle in the market.

Charging of electric vehicles tends to occur relatively frequently for users in situations where the electric vehicles can be charged in homes of the users, for example, without fully utilizing the full range (driving distance) of an electric vehicle. This approach may be followed by a user because it is not clear whether next time it will be possible for the electric vehicle to be driven with a remaining battery capacity.

However, in reality, even if the battery is not fully charged, a next occurrence of driving is often possible, and the more frequent batteries are charged or fully charged, the more the battery life may be shortened.

### SUMMARY

The present disclosure provides an apparatus and a method for recommending charging of a battery in an electric vehicle, which can provide a recommendation for battery charging to a driver by probabilistically predicting whether driving will be possible at a next day with a current battery charging capacity when a driver of an electric vehicle intends to finish driving.

The object to be achieved by the present disclosure is not limited to the aforementioned object, and other objects, which are not mentioned above, will be apparent to a person having ordinary skill in the art from the following description.

An aspect of the present disclosure provides an apparatus for recommending charging of a battery in an electric vehicle, which includes: a battery consumption measurement module for measuring a daily battery consumption of the battery; a distribution model generation module for generating a distribution model for the daily battery consumption by using the measured daily battery consumption; and a recommendation module for providing a recommendation for battery charging based on the distribution model and a current state of charge (SOC) of the battery.

The battery consumption module may measure the daily battery consumption of the battery on a daily basis.

The distribution model generation module and the recommendation module may be provided in a controller having at least one processor and memory.

The distribution model generation module may generate a normal distribution model for the daily battery consumption by using an average and a standard deviation of the measured daily battery consumption.

The battery consumption measurement module may cluster the measured daily battery consumption for each day type, the distribution model generation module may generate the normal distribution model for the daily battery consumption of the corresponding day type by using the average and the standard deviation of the daily battery consumption clustered for each day type, and the recommendation module may provide the recommendation for the battery charging based on a normal distribution model for a daily battery consumption of a day type of a next day, and the current SOC.

The day type may include a weekday, a weekend, a weekend holiday, and a weekday holiday.

The recommendation module may calculate a complete battery consumption probability of the next day based on the normal distribution model and the current SOC, and recommend the battery charging when the complete battery consumption probability is equal to or more than a predetermined threshold.

The normal distribution model may be generated according to the following equation:

$$P ( x ) = \frac{1}{σ \sqrt{2 π}} exp ( - \frac{{( x - μ )}^{2}}{2 {σ}^{2}} ) ,$$

where μ and σ represent the average and the standard deviation of the measured daily battery consumption, respectively.

The complete battery consumption probability may be calculated according to the following equation:

$${\int }_{K}^{∞} P ( x ) dx ,$$

where K represents the current SOC of the battery.

When the measured daily battery consumption deviates from a predetermined range based on the average and the standard deviation of the normal distribution model of the corresponding day type, the battery consumption measurement module may regard the daily battery consumption as abnormal data, and prevent the measured data from being used for generating the normal distribution model.

A vehicle may include the above-described apparatus.

Another aspect of the present disclosure provides a method for recommending charging of a battery in an electric vehicle, which includes: measuring, by a controller, a daily battery consumption of the battery; generating, by the controller, a distribution model for the daily battery consumption by using the measured daily battery consumption; and providing, by the controller, a recommendation for charging of the battery based on the distribution model and a current state of charge (SOC) of the battery.

In the generating of the distribution model, a normal distribution model for the daily battery consumption may be generated by using an average and a standard deviation of the measured daily battery consumption.

The method may further include clustering the measured daily battery consumption for each day type, and in the generating of the distribution model, the normal distribution model for the daily battery consumption of the corresponding day type may be generated by using the average and the standard deviation of the daily battery consumption clustered for each day type, and in the providing of the recommendation, the recommendation for the battery charging may be provided based on a normal distribution model for a daily battery consumption of a day type of a next day, and the current SOC.

The day type may include a weekday, a weekend, a weekend holiday, and a weekday holiday.

In the providing of the recommendation, a complete battery consumption probability of the next day may be calculated based on the normal distribution model and the current SOC, and the battery charging may be recommended when the complete battery consumption probability is equal to or more than a predetermined threshold.

In the measuring, when the measured daily battery consumption deviates from a predetermined range based on the average and the standard deviation of the normal distribution model of the corresponding day type, the daily battery consumption may be regarded as abnormal data, and the measured data may be prevented from being used for generating the normal distribution model.

A further aspect of the present disclosure provides a non-transitory computer readable medium containing program instructions executed by a processor, the computer readable medium including: program instructions that measure a daily battery consumption of a battery; program instructions that generate a distribution model for the daily battery consumption by using the measured daily battery consumption; and program instructions that provide a recommendation for charging of the battery based on the distribution model and a current state of charge (SOC) of the battery.

According to an exemplary embodiment of the present disclosure, a recommendation for battery charging can be provided to a driver by probabilistically predicting whether driving will be possible the next day with a current battery charging capacity when a driver of an electric vehicle intends to finish driving.

Therefore, convenience can be provided for the driver to make a determination on whether to charge a battery, and frequent battery charging which is not required can be suppressed. Accordingly, a wider range of SOC can be used with one charging, and a battery life can be enhanced by reducing the number of charging or full charging times.

The effect of the present disclosure is not limited to the aforementioned effect, and other effects, which are not mentioned above, will be apparent to a person having ordinary skill in the art from the following description.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a block diagram illustrating an apparatus for recommending a charging battery in an electric vehicle according to an exemplary embodiment of the present disclosure.

FIG. 2 illustrates an example in which a daily battery consumption is clustered for each day type.

FIG. 3 illustrates an example of a normal distribution model of the daily battery consumption for each day type generated based on FIG. 2.

FIGS. 4A and 4B illustrate an example in which a complete battery consumption probability for the next day is calculated according to the normal distribution model of the daily battery consumption and a current SOC.

FIG. 5 is a flowchart illustrating a process of generating a normal distribution model for a daily battery consumption in a method for recommending a charging battery in an electric vehicle according to an exemplary embodiment of the present disclosure.

FIG. 6 is a flowchart illustrating a process of providing a recommendation for battery charging based on the normal distribution model for the daily battery consumption and the current SOC of a battery in the method for recommending a charging battery in an electric vehicle according to an exemplary embodiment of the present disclosure.

It should be understood that the appended drawings are not necessarily to scale, presenting a somewhat simplified representation of various features illustrative of the basic principles of the disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles. The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Hereinafter, preferred embodiments of the present disclosure will be described in detail with reference to the drawings. In the following descriptions and the accompanying drawings, substantially the same components are represented by the same reference numerals, and the duplicate description will be omitted. Further, in describing the present disclosure, a detailed explanation of a known related function or configuration may be omitted to avoid unnecessarily obscuring the subject matter of the present disclosure.

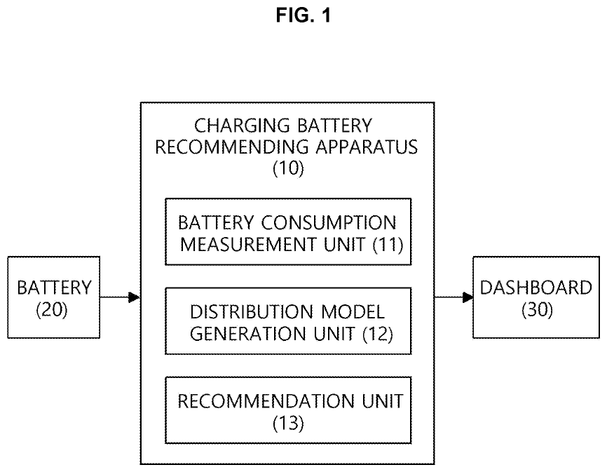

FIG. 1 is a block diagram illustrating an apparatus for recommending a charging battery in an electric vehicle according to an exemplary embodiment of the present disclosure.

The charging battery recommending apparatus 10 according to the exemplary embodiment of the present disclosure is configured to include a battery consumption measurement unit/module 11, a distribution model generation unit/module 12, and a recommendation unit/module 13.

Each of the above units/modules may constitute modules and/or devices of the charging battery recommending apparatus 10, which may be a controller. For example, the above units of the charging battery recommending apparatus 100 may constitute hardware components that form part of a controller (e.g., modules or devices of a high-level controller), or may constitute individual controllers each having a processor and memory. The charging battery recommending apparatus 100 may include one or more processors and memory.

The battery consumption measurement unit 11 measures a daily battery consumption of a battery 20, e.g., which may occur daily. A time of measuring the daily battery consumption may be set by default or preset by a user. For example, when the measurement time is set to 4 a.m., the battery consumption measurement unit 11 may measure a battery consumption consumed during the corresponding day when 4 a.m. is reached.

The distribution model generation unit 12 generates and stores a distribution model for the daily battery consumption by using the daily battery consumption measured through the battery consumption measurement unit 11. Here, the distribution model may be a normal distribution model. That is, the distribution model generation unit 12 may calculate an average and a standard deviation of measured daily battery consumptions, and generate the normal distribution model for the daily battery consumption by using the average and the standard deviation.

The distribution model generation unit 12 may generate the normal distribution model for the daily battery consumption for each day type. In the exemplary embodiment of the present disclosure, the day type may include a weekday, a weekend, a weekend holiday, and a weekday holiday. The battery consumption measurement unit 11 may cluster the measured daily battery consumption for each data type so as to generate the normal distribution model for each day type. That is, the battery consumption measurement unit 11 may cluster the measured daily battery consumption for each of the weekdays, the weekend, the weekend holidays, and the weekday holidays.

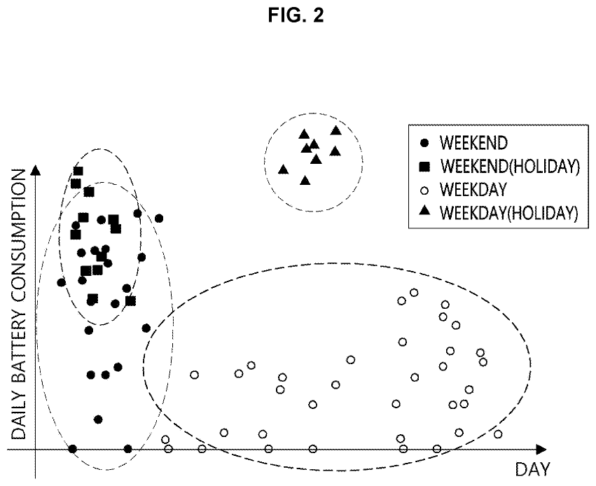

FIG. 2 illustrates an example in which a daily battery consumption is clustered for each day type. Referring to FIG. 2, it can be seen that distributions of the daily battery consumptions are bundled in a predetermined area according to the weekday, the weekend, the weekend holiday, and the weekday holiday, and bundled patterns are different.

The distribution model generation unit 12 may generate the normal distribution model for the daily battery consumption of the corresponding day type by using the average and the standard deviation of the daily battery consumption measurement values clustered for each day type. That is, the distribution model generation unit 12 may generate a normal distribution model for a daily battery consumption of the weekday by using an average and a standard deviation of measurement values clustered during the weekday, generate a normal distribution model for a daily battery consumption of the weekend by using an average and a standard deviation of measurement values clustered during the weekend, generate a normal distribution model for a daily battery consumption of the weekend holiday by using an average and a standard deviation of measurement values clustered during the weekend holiday, and generate a normal distribution model for a daily battery consumption of the weekday holiday by using an average and a standard deviation of measurement values clustered during the weekday holiday.

For any day type, the normal distribution model of the daily battery consumptions may be generated according to the following equation:

$$P ( x ) = \frac{1}{σ \sqrt{2 π}} exp ( - \frac{{( x - μ )}^{2}}{2 {σ}^{2}} ) . \qquad [ Equation 1 ]$$

Here, μ and σ represent the average and the standard deviation of the daily battery consumption in the corresponding day type, respectively.

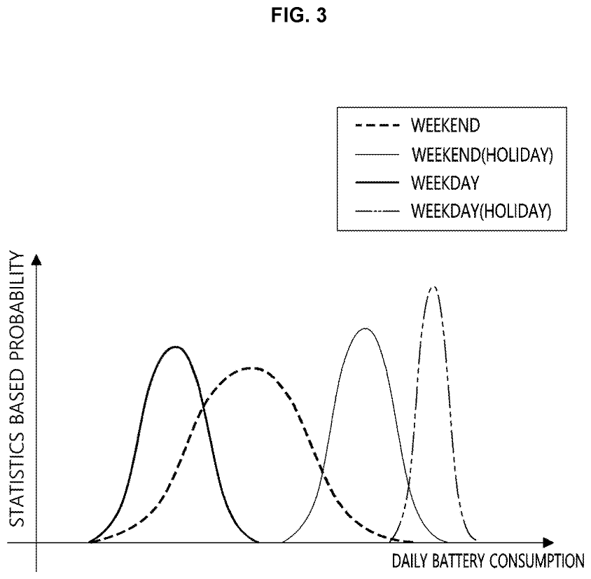

FIG. 3 illustrates an example of a normal distribution model of the daily battery consumption for each day type generated based on FIG. 2.

Referring to FIG. 3, the daily battery consumption of the weekday is represented as a normal distribution model (thick solid line) in which the average and the standard deviation are comparatively small, and the daily battery consumption of the weekend is represented as a normal distribution model (dotted line) in which both the average and the standard deviation are comparatively large as compared with the weekday. The reason is that the daily battery consumption is comparatively small and fluctuation thereof is small due to commute to work on the weekdays, while the daily battery consumption is comparatively large and the fluctuation is large due to leisure and travel on the weekends. Meanwhile, on the weekend holiday and the weekday holiday, the average is comparatively large and the standard deviation is comparatively small, so the average and the standard deviation are represented as normal distribution models such as a solid line and dotted lines, respectively.

Meanwhile, when the measured daily battery consumption deviates from a predetermined range based on an average and a standard deviation of the normal distribution model for each day type, which are prestored, the battery consumption measurement unit 11 regards the daily battery consumption as abnormal data, and excludes the daily battery consumption to prevent the measured data from being used for generating the normal distribution model. For example, when the prestored average and standard deviation of the normal distribution model of the corresponding day type are μ and σ, respectively, if the measured daily battery consumption is μ−3σ or less or μ+3σ or more, the measurement value may be regarded as the abnormal data and excluded. That is, when the measured daily battery consumption is between μ−3σ and μ+3σ, the measured daily battery consumption may be used as a new measurement value for updating the average and the standard deviation of the normal distribution model, and in this case, an oldest measurement value may be deleted, and the average and the standard deviation may be obtained.

Referring back to FIG. 1, when a start-off signal is generated in the vehicle, the recommendation unit 13 checks a current state of charge (SOC) of the battery 20, and determines a recommendation for battery charging based on the normal distribution model for the daily battery consumption stored in the distribution model generation unit 12 and the current SOC of the battery 20, and provides the determined recommendation through a dashboard 30 of the vehicle. Here, the recommendation unit 13 may provide the recommendation for the battery charging based on the normal distribution model for the day type at the next day and the current SOC of the battery 20. For example, the recommendation unit 13 may provide the recommendation for the battery charging based on the normal distribution model of the daily battery consumption for the weekday and the current SOC when the next day is the weekday, and provide the recommendation for the battery charging based on the normal distribution model of the daily battery consumption for the weekend and the current SOC when the next day is the weekend.

The recommendation unit 13 may calculate a probability that the battery will be completely consumed at the next day based on the normal distribution model for the day type at the next day and the current SOC of the battery 20, and output a message for recommending charging the battery to the driver through the dashboard 30 when the complete battery consumption probability is equal to or more than a predetermined threshold. Here, the predetermined threshold may be set by default or set by the user. For example, when the threshold is set to 0.3, the message for recommending charging the battery may be output through the dashboard 30 if the complete battery consumption probability for the next day is equal to or more than 0.3.

When it is assumed that the normal distribution model for the daily battery consumption of the day type at the next data is P(x), and the current SOC of the battery 20 is K, the complete battery consumption probability may be calculated by integrating P(x) with respect to K or more as in the following equation:

$${\int }_{K}^{∞} P ( x ) dx . \qquad [ Equation 2 ]$$

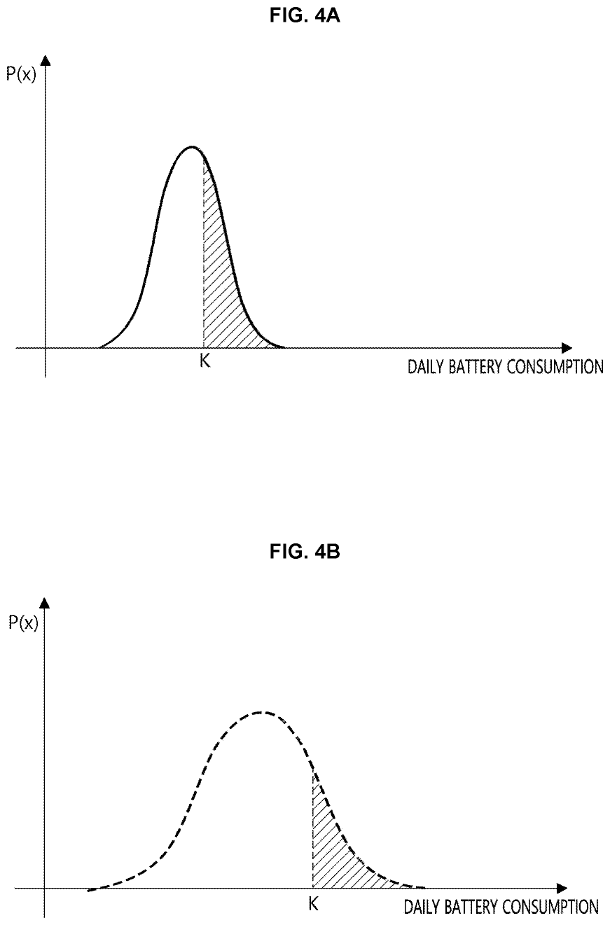

FIGS. 4A and 4B illustrate an example in which a complete consumption probability of a battery for the next day is calculated according to the normal distribution model of the daily battery consumption and a current SOC.

FIG. 4A illustrates the normal distribution model (see FIG. 3) for the daily battery consumption of the weekday, and the next-day complete battery consumption probability calculated according to the current SOC K of the battery 20 becomes a width of a colored part. When the complete battery consumption probability calculated in FIG. 4A is 0.4, and the threshold is 0.3, the message for recommending charging the battery will be output through the dashboard 30.

FIG. 4B illustrates the normal distribution model (see FIG. 3) for the daily battery consumption for the weekend, and the next-day complete battery consumption probability calculated according to the current SOC K of the battery 20 becomes the width of the colored part. When the complete battery consumption probability calculated in FIG. 4B is 0.2, and the threshold is 0.3, the message for recommending charging the battery will not be output through the dashboard 30.

According to the exemplary embodiment, the recommendation unit 13 may also output the message for recommending charging the battery, and a probability value that the battery will be completely consumed for the next day through the dashboard 30. In other words, in FIG. 4A, a message “The complete battery consumption probability for tomorrow's driving is 40%. It would be better to charge the battery.” may be output.

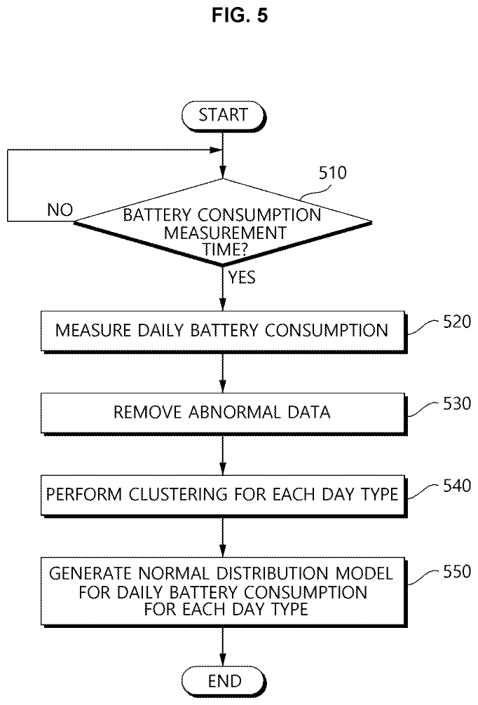

FIG. 5 is a flowchart illustrating a process of generating a normal distribution model for a daily battery consumption in a method for recommending a charging battery in an electric vehicle according to an exemplary embodiment of the present disclosure. When a battery consumption measurement time is reached (step 510), a battery consumption measurement unit 11 measures a daily battery consumption daily (step 520).

When the measured daily battery consumption deviates from a predetermined range (e.g., μ−3σ to μ+3σ) based on an average and a standard deviation of the normal distribution model for each day type, which are prestored, the battery consumption measurement unit 11 regards the daily battery consumption as abnormal data, and removes the daily battery consumption (step 530).

The battery consumption measurement unit 11 clusters the measured daily battery consumption for each day type, i.e., for each of a weekday, a weekend, a weekend holiday, and a weekday holiday (step 540).

The distribution model generation unit 12 generates the normal distribution model for the daily battery consumption of the corresponding day type by using the average and the standard deviation of the daily battery consumption measurement values clustered for each day type (step 550).

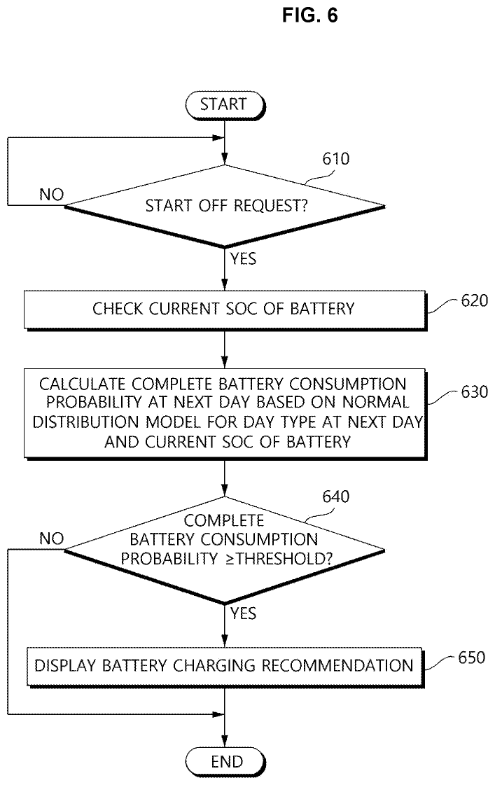

FIG. 6 is a flowchart illustrating a process of providing a recommendation for battery charging based on the normal distribution model for the daily battery consumption and the current SOC of a battery in the method for recommending a charging battery in an electric vehicle according to an exemplary embodiment of the present disclosure.

When a start off request is generated in a vehicle (step 610), the recommendation unit 13 checks a current SOC of a battery 20 (step 620).

The recommendation unit 13 calculates a probability that the battery will be completely consumed for the next day based on the normal distribution model for the day type for the next day and the current SOC of the battery 20 (step 630).

When a complete battery consumption probability is equal to or more than a predetermined threshold (step 640), the recommendation unit 13 displays a message for recommending charging the battery to a driver through a dashboard 30 (step 650).

According to the exemplary embodiment of the present disclosure, when the driver tries to terminate the driving, the complete battery consumption probability is calculated based on the current SOC of the current battery, and when it is predicted that driving is impossible at a predetermined probability or more, it may be recommended that the battery will be charged to the driver. Accordingly, the driver can drive the vehicle for a long time without worrying about the battery discharge, and the battery SOC can be used over a wider range, and the battery life can be improved by reducing the number of battery charging or full charging times.

Combinations of each block of the block diagram accompanied in the present disclosure and each step of the flowchart may be performed by computer program instructions. Since computer program instructions may be mounted on a universal computer, a special computer or a processor of other programmable data processing equipment, the instructions performed by the computer or a processor of other programmable data processing equipment generate a means of performing functions described in each block of the block diagram or each step of the flowchart. Since the computer program instructions may also be stored in a computer usable or computer readable memory which may direct a computer or other programmable data processing equipment in order to implement a function in a specific scheme, the instructions stored in the computer usable or computer readable memory can also produce manufacturing items including an instruction means performing a function described in each block of the block diagram or each step in the flowchart. Since the computer program instructions can also be mounted on the computer or other programmable data processing equipment, instructions that perform the computer or other programmable data processing equipment by generating a processor executed by the computer as a series of operational steps are performed on the computer or other programmable data processing equipment can provide steps for executing the functions described in each block of the block diagram or each step in the flowchart.

Each block or each step may represent a part of a module, a segment, or a code that includes one or more executable instructions for executing a specified logical function(s). It should also be noted that in some alternative embodiments, the functions mentioned in the blocks or steps may occur out of order. For example, two successive blocks or steps illustrated may in fact be performed substantially concurrently or the blocks or steps may be sometimes performed in a reverse order according to the corresponding function.

As described above, the exemplary embodiments have been described and illustrated in the drawings and the specification. The exemplary embodiments were chosen and described in order to explain certain principles of the disclosure and their practical application, to thereby enable others skilled in the art to make and utilize various exemplary embodiments of the present disclosure, as well as various alternatives and modifications thereof. As is evident from the foregoing description, certain aspects of the present disclosure are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the disclosure are deemed to be covered by the disclosure which is limited only by the claims which follow.

What is claimed is:

1. An apparatus for recommending charging of a battery in an electric vehicle, the apparatus comprising:
a battery consumption measurement module configured to measure a daily battery consumption of the battery;
a distribution model generation module configured to generate a distribution model for the daily battery consumption by using the measured daily battery consumption; and
a recommendation module configured to provide a recommendation for charging of the battery based on the distribution model and a current state of charge (SOC) of the battery.

2. The apparatus of claim 1, wherein the battery consumption module is configured to measure the daily battery consumption of the battery on a daily basis.

3. The apparatus of claim 1, wherein the battery consumption measurement module, the distribution model generation module, and the recommendation module are provided in a controller having at least one processor and memory.

4. The apparatus of claim 1, wherein the distribution model generation module generates a normal distribution model for the daily battery consumption by using an average and a standard deviation of the measured daily battery consumption.

5. The apparatus of claim 4, wherein:
the battery consumption measurement module clusters the measured daily battery consumption for each day type,
the distribution model generation module generates the normal distribution model for the daily battery consumption of the corresponding day type by using the average and the standard deviation of the daily battery consumption clustered for each day type, and
the recommendation module provides the recommendation for the battery charging based on a normal distribution model for a daily battery consumption of a day type of a next day, and the current SOC.

6. The apparatus of claim 5, wherein the day type includes a weekday, a weekend, a weekend holiday, and a weekday holiday.

7. The apparatus of claim 6, wherein the recommendation module calculates a complete battery consumption probability of the next day based on the normal distribution model and the current SOC, and recommends the battery charging when the complete battery consumption probability is equal to or more than a predetermined threshold.

8. The apparatus of claim 7, wherein the normal distribution model is generated according to the following equation:
$$P ( x ) = \frac{1}{σ \sqrt{2 π}} exp ( - \frac{{( x - μ )}^{2}}{2 {σ}^{2}} ) ,$$
wherein μ and σ represent the average and the standard deviation of the measured daily battery consumption, respectively.

9. The apparatus of claim 8, wherein the complete battery consumption probability is calculated according to the following equation:
$${\int }_{K}^{∞} P ( x ) dx ,$$
wherein K represents the current SOC of the battery.

10. The apparatus of claim 5, wherein when the measured daily battery consumption deviates from a predetermined range based on the average and the standard deviation of the normal distribution model of the corresponding day type, the battery consumption measurement module regards the daily battery consumption as abnormal data, and prevents the measured data from being used for generating the normal distribution model.

11. A vehicle comprising the apparatus of claim 1.

12. A method for recommending charging of a battery in an electric vehicle, the method comprising:
measuring, by a controller, a daily battery consumption of the battery;
generating, by the controller, a distribution model for the daily battery consumption by using the measured daily battery consumption; and
providing, by the controller, a recommendation for charging of the battery based on the distribution model and a current state of charge (SOC) of the battery.

13. The method of claim 12, wherein in the generating of the distribution model, a normal distribution model for the daily battery consumption is generated by using an average and a standard deviation of the measured daily battery consumption.

14. The method of claim 13, further comprising:
clustering the measured daily battery consumption for each day type,
wherein in the generating of the distribution model, the normal distribution model for the daily battery consumption of the corresponding day type is generated by using the average and the standard deviation of the daily battery consumption clustered for each day type, and
in the providing of the recommendation, the recommendation for the battery charging is provided based on a normal distribution model for a daily battery consumption of a day type of a next day, and the current SOC.

15. The method of claim 14, wherein the day type includes a weekday, a weekend, a weekend holiday, and a weekday holiday.

16. The method of claim 13, wherein in the providing of the recommendation, a complete battery consumption probability of the next day is calculated based on the normal distribution model and the current SOC, and the battery charging is recommended when the complete battery consumption probability is equal to or more than a predetermined threshold.

17. The method of claim 16, wherein the normal distribution model is generated according to the following equation:
$$P ( x ) = \frac{1}{σ \sqrt{2 π}} exp ( - \frac{{( x - μ )}^{2}}{2 {σ}^{2}} ) ,$$
wherein μ and σ represent the average and the standard deviation of the measured daily battery consumption, respectively.

18. The method of claim 17, wherein the complete battery consumption probability is calculated according to the following equation:
$${\int }_{K}^{∞} P ( x ) dx ,$$
wherein K represents the current SOC of the battery.

19. The method of claim 14, wherein in the measuring, when the measured daily battery consumption deviates from a predetermined range based on the average and the standard deviation of the normal distribution model of the corresponding day type, the daily battery consumption is regarded as abnormal data, and the measured data is prevented from being used for generating the normal distribution model.

20. A non-transitory computer readable medium containing program instructions executed by a processor, the computer readable medium comprising:
program instructions that measure a daily battery consumption of a battery;
program instructions that generate a distribution model for the daily battery consumption by using the measured daily battery consumption; and
program instructions that provide a recommendation for charging of the battery based on the distribution model and a current state of charge (SOC) of the battery.
